(19) United States
(12) Patent Application Publication
(10) Pub. No.: US 2024/0387640 A1
(43) Pub. Date: Nov. 21, 2024

(54) SiC CRYSTAL SUBSTRATE, METHOD OF MANUFACTURING SiC CRYSTAL SUBSTRATE, SiC EPITAXIAL SUBSTRATE, AND METHOD OF MANUFACTURING SiC EPITAXIAL SUBSTRATE

(71) Applicant: SUMITOMO ELECTRIC INDUSTRIES, LTD., Osaka (JP)

(72) Inventors: Issei SATOH, Osaka (JP); Shigeaki UEMURA, Osaka (JP); Shin HARADA, Osaka (JP)

(73) Assignee: SUMITOMO ELECTRIC INDUSTRIES, LTD., Osaka (JP)

(21) Appl. No.: 18/694,182

(22) PCT Filed: Aug. 31, 2022
(86) PCT No.: PCT/JP2022/032803

§ 371 Date: Mar. 21, 2024

(30) Foreign Application Priority Data
Sep. 27, 2021 (JP) 2021-156610

(51) Int. Cl. H01L 29/16; G01N 23/085; G01N 23/2273; H01L 21/304

(52) U.S. Cl. CPC H01L 29/1608; G01N 23/085; G01N 23/2273; H01L 21/304

(57) ABSTRACT

In an X-ray photoelectron spectrum under conditions of incident X-ray energy of 250 eV and a photoelectron take-off angle of 45 degree, when a sum of an area of Si 2p_{1/2} spectrum and an area of Si 2p_{3/2} spectrum is 1, a sum of an area of a Si²⁺ spectrum, an area of a Si³⁺ spectrum, and an area of a Si⁴⁺ spectrum is smaller than 1.8.

### TECHNICAL FIELD

The present disclosure relates to an SiC crystal substrate, a method of manufacturing an SiC crystal substrate, an SiC epitaxial substrate, and a method of manufacturing an SiC epitaxial substrate. This application claims priority based on Japanese Patent Application No. 2021-156610 filed on Sep. 27, 2021. The entire contents of the Japanese patent application are incorporated herein by reference.

### BACKGROUND ART

WO 2011/158557 (PTL 1) describes a method of cleaning a silicon carbide (SiC) semiconductor.

### CITATION LIST

### Patent Literature

PTL 1: WO 2011/158557

### SUMMARY OF INVENTION

In an SiC crystal substrate according to the present disclosure, in an X-ray photoelectron spectrum under conditions of an incident X-ray energy of 250 eV and a photoelectron take-off angle of 45 degrees, when a sum of an area of a Si 2p_{1/2} spectrum and an area of a Si 2p_{3/2} spectrum is 1, a sum of an area of a Si²⁺ spectrum, an area of a Si³⁺ spectrum, and an area of a Si⁴⁺ spectrum is smaller than 1.8.

In an SiC crystal substrate according to the present disclosure, in an X-ray photoelectron spectrum under conditions of an incident X-ray energy of 100 eV and a photoelectron take-off angle of 45 degrees, when a sum of an area of a Si 2p_{1/2} spectrum and an area of a Si 2p_{3/2} spectrum is 1, a sum of an area of a Si²⁺ spectrum, an area of a Si³⁺ spectrum, and an area of a Si⁴⁺ spectrum is smaller than 4.1.

A method of manufacturing an SiC crystal substrate according to the present disclosure includes the following steps. A chemical mechanical polishing is performed on an SiC substrate. After performing the chemical mechanical polishing on the SiC substrate, a beam of a cluster of noble gas ions is applied to a surface of the SiC substrate.

An SiC epitaxial substrate according to the present disclosure include an SiC crystal substrate, and an SiC epitaxial film disposed on the SiC crystal substrate. An area ratio of a polycrystal region in a surface of the SiC epitaxial film is less than 10%.

### BRIEF DESCRIPTION OF THE DRAWINGS

FIG. 1 is a schematic cross-sectional view showing a configuration of an SiC crystal substrate according to an embodiment.

FIG. 2 is a partial schematic cross-sectional view showing a measure state of an X-ray photoelectron spectrum of an SiC crystal substrate.

FIG. 3 is a schematic view showing an X-ray photoelectron spectrum of an SiC crystal substrate in an embodiment.

FIG. 4 is a schematic view showing a spectrum subjected to waveform separation.

FIG. 5 is a schematic view showing an area of a Si²⁺ spectrum, an area of a Si³⁺ spectrum, and an area of a Si⁴⁺ spectrum.

FIG. 6 is a schematic view showing an area of a Si 2p_{1/2} spectrum and an area of a Si 2p_{3/2} spectrum.

FIG. 7 is a schematic view showing an X-ray absorption coefficient spectrum of an SiC crystal substrate in the embodiment.

FIG. 8 is a flow chart schematically showing a method of manufacturing an SiC crystal substrate according to an embodiment.

FIG. 9 is a schematic cross-sectional view showing a configuration of an SiC substrate.

FIG. 10 is a schematic cross-sectional view showing a step of performing chemical mechanical polishing on an SiC substrate.

FIG. 11 is a schematic cross-sectional view showing a step of applying a beam of a cluster of noble gas ions to a surface of an SiC substrate.

FIG. 12 is a flow chart schematically showing a method of manufacturing an SiC epitaxial substrate according to an embodiment.

FIG. 13 is a schematic cross-sectional view showing a configuration of an SiC epitaxial substrate according to an embodiment.

### DETAILED DESCRIPTION

### Problems to be Solved by Present Disclosure

An object of the present disclosure is to reduce a rate of generation of polycrystal in an SiC epitaxial film.

### Advantageous Effect of Present Disclosure

According to the present disclosure, the rate of generation of polycrystal in the SiC epitaxial film can be reduced.

### Overview of Embodiments of Present Disclosure

First, an overview of embodiments of the present disclosure will be described.
(1) In an SiC crystal substrate 10 according to the present disclosure, in an X-ray photoelectron spectrum 20 under conditions of an incident X-ray energy of 250 eV and a photoelectron take-off angle of 45 degrees, when a sum of an area of a Si 2p_{1/2} spectrum 41 and an area of a Si 2p_{3/2} spectrum 42 is 1, a sum of an area of a Si²⁺ spectrum 33, an area of a Si³⁺ spectrum 32, and an area of a Si⁴⁺ spectrum 31 is smaller than 1.8.
(2) In SiC crystal substrate 10 according to (1) above, when the sum of the area of Si 2p_{1/2} spectrum 41 and the area of 2p_{3/2} spectrum 42 is 1, the sum of the area of Si²⁺ spectrum 33, the area of Si³⁺ spectrum 32, and the area of Si⁴⁺ spectrum 31 may be smaller than 1.1.
(3) In an SiC crystal substrate 10 according to the present disclosure, in an X-ray photoelectron spectrum under conditions of an incident X-ray energy of 100 eV and a photoelectron take-off angle of 45 degrees, when a sum of an area of a Si 2p_{1/2} spectrum and an area of a Si 2p_{3/2} spectrum is 1, a sum of an area of a Si²⁺ spectrum, an area of a Si³⁺ spectrum, and an area of a Si⁴⁺ spectrum is smaller than 4.1.
(4) In SiC crystal substrate 10 according to (3) above, when the sum of the area of the Si 2p_{1/2} spectrum and the area of the Si 2p_{3/2} spectrum is 1, the sum of the area of the Si²⁺ spectrum, the area of the Si³⁺ spectrum, and the area of the Si⁴⁺ spectrum may be smaller than 3.0.
(5) In SiC crystal substrate 10 according to (1) or (4) above, when an X-ray absorption coefficient of a peak between 1840 eV and 1850 eV of X-ray absorption coefficient spectrum 60 is 1, an X-ray absorption coefficient of a peak between 1855 eV and 1865 eV of X-ray absorption coefficient spectrum 60 may be larger than 0.45.
(6) In SiC crystal substrate 10 according to (5) above, when the X-ray absorption coefficient of the peak between 1840 eV and 1850 eV of X-ray absorption coefficient spectrum 60 is 1, the X-ray absorption coefficient of the peak between 1855 eV and 1865 eV of X-ray absorption coefficient spectrum 60 may be larger than 0.55.
(7) An SiC epitaxial substrate according to the present disclosure includes the SiC crystal substrate according to any one of (1) to (6) above, and an SiC epitaxial film disposed on the SiC crystal substrate.
(8) A method of manufacturing SiC crystal substrate 10 according to the present disclosure includes the following steps. Chemical mechanical polishing is performed on an SiC substrate 50. After the performing chemical mechanical polishing, a beam of a cluster of noble gas ions is applied to a surface of SiC substrate 50.
(9) In the method of manufacturing SiC crystal substrate 10 according to (8) above, in the applying a beam, an acceleration voltage may be 5 kV to 10 kV.
(10) In the method of manufacturing SiC crystal substrate 10 according to (8) or (9) above, in the applying a beam, a current of the beam may be 5 nA to 10 nA.
(11) In the method of manufacturing SiC crystal substrate 10 according to (8) to (10) above, in the applying a beam, the surface is scanned by the beam. An area of a region to which the beam is applied may be 1 mm² to 100 mm².
(12) A method of manufacturing an SiC epitaxial substrate 100 according to the present disclosure includes the following steps. An SiC crystal substrate 10 manufactured by the method of manufacturing SiC crystal substrate 10 according to any one of (8) to (11) above is provided. After the applying a beam, an SiC epitaxial film 70 is formed on SiC crystal substrate 10.
(13) An SiC epitaxial substrate 100 according to the present disclosure include an SiC crystal substrate 10, and an SiC epitaxial film 70 disposed on SiC crystal substrate 10. An area ratio of a polycrystal region 71 in a surface 5 of SiC epitaxial film 70 is less than 10%.

### Detailed Description of Embodiments

Hereinafter, details of embodiments of the present disclosure (hereinafter, also referred to as the embodiments) will be described in detail with reference to the drawings. In the drawings, the same or corresponding portions are denoted by the same reference characters, and description thereof will not be repeated.

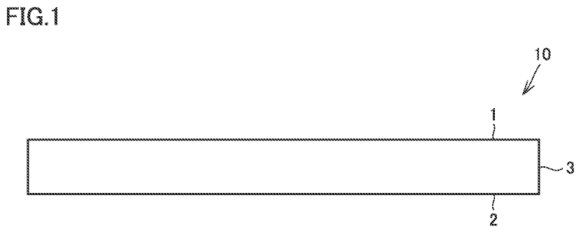

First, a configuration of an SiC crystal substrate 10 according to the embodiment will be described. FIG. 1 is a schematic cross-sectional view showing the configuration of SiC crystal substrate 10 according to the embodiment. As shown in FIG. 1, SiC crystal substrate 10 according to the embodiment has a first main surface 1, a second main surface 2, and an outer peripheral surface 3. Second main surface 2 is opposite to first main surface 1. Outer peripheral surface 3 is contiguous with each of first main surface 1 and second main surface 2. Outer peripheral surface 3 is, for example, a cylindrical surface. Each of first main surface 1 and second main surface 2 is, for example, planar.

First main surface 1 is, for example, a {0001} plane or a plane inclined by an off angle with respect to the {0001} plane. Specifically, first main surface 1 may be a surface inclined by an off angle with respect to a (0001) plane or the (0001) plane, or may be a surface inclined by an off angle with respect to a (000-1) plane or the (000-1) plane. The off angle may be, for example, five degrees or less, or three degrees or less. An off direction may be, for example, a <11-20> direction.

A diameter of first main surface 1 is, for example, four inches. The diameter of first main surface 1 is not particularly limited, and may be, for example, five inches or more, or six inches or more. The diameter of first main surface 1 is not particularly limited, but may be, for example, eight inches or less. In this specification, four inches means 100 mm or 101.6 mm (4 inches×25.4 mm/inch). Five inches means 125 mm or 127.0 mm (5 inches×25.4 mm/inch). Six inches means 150 mm or 152.4 mm (6 inches×25.4 mm/inch). Eight inches means 200 mm or 203.2 mm (8 inches×25.4 mm/inch).

### (X-ray Photoelectron Spectroscopy: XPS)

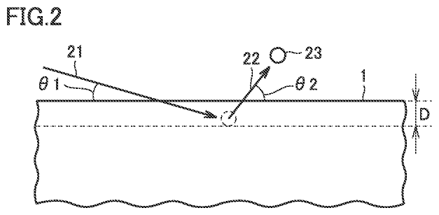

FIG. 2 is a partial schematic cross-sectional view showing a measure state of an X-ray photoelectron spectrum 20 of SiC crystal substrate 10. X-ray photoelectron spectrum 20 is measured using Sumitomo Electric Beamline BL17 in SAGA Light Source. Sumitomo Electric Beamline BL17 is a soft X-ray Beamline. A light source of Sumitomo Electric Beamline BL17 uses a polarizing electromagnet. A white X-ray emitted from the light source is selected into an incident X-ray having a necessary energy by a spectroscope using a diffraction grating. Synchrotron radiation is used as the incident X-ray.

The incident X-ray is applied to first main surface 1 of SiC crystal substrate 10. As shown in FIG. 2, an angle formed by an incident direction 21 of the incident X-ray and first main surface 1 is an incident angle θ1 of the incident X-ray. The analysis depth D of the incident X-ray is, for example, 2 nm or less. Photoelectrons 23 are emitted from the vicinity of first main surface 1 of SiC crystal substrate 10. Photoelectrons 23 are detected by a detector (not shown). An angle formed by a take-off direction 22 of photoelectrons 23 and first main surface 1 is a photoelectron take-off angle θ2.

The incident energy of X-ray when measuring X-ray photoelectron spectrum 20 of SiC crystal substrate 10 in the embodiment is 100 eV or 250 eV. The incident X-ray is incident on first main surface 1 at the incident angle θ1. The incident angle θ1 of the incident X-ray is, for example, 45 degrees. The photoelectron take-off angle θ2 is 45 degrees.

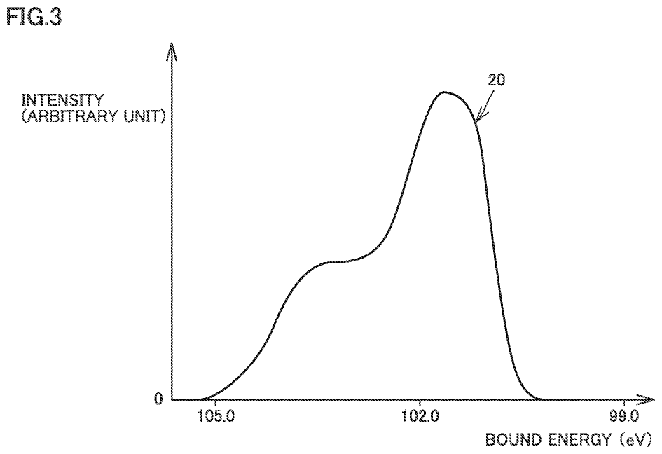

FIG. 3 is a schematic view showing X-ray photoelectron spectrum 20 of SiC crystal substrate 10 in the embodiment. In FIG. 3, the horizontal axis represents a bound energy (unit: eV). The vertical axis represents an intensity of photoelectron (unit: arbitrary unit). An X-ray photoelectron spectrum is often analyzed after background processing. As a background subtraction method used in the X-ray photoelectron spectrum, there is a Shirley method or the like. As an example, FIG. 3 shows the X-ray photoelectron spectrum obtained by applying the Shirley method to a range of the bound energy from 99.0 eV to 108 eV. The intensity of the photoelectron may be normalized. The bound energy is calibrated with Au 4f_{7/2} as 84 eV.

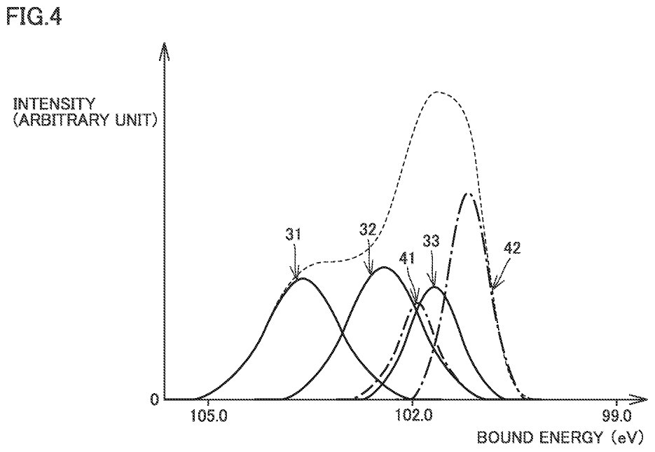

FIG. 4 is a schematic view showing a spectrum subjected to waveform separation. X-ray photoelectron spectrum 20 of SiC crystal substrate 10 is subjected to waveform separation by setting five spectra of a Si 2p_{1/2} spectrum 41, a Si 2p_{3/2} spectrum 42, a Si²⁺ spectrum 33, a Si³⁺ spectrum 32, and a Si⁴⁺ spectrum 31 using spectrum analysis software. The spectrum analysis software is, for example, MultiPak (trademark) manufactured by ULVAC-PHI, Inc.

Si 2p_{1/2} spectrum 41 and Si 2p_{3/2} spectrum 42 are related to a bond between silicon (Si) and carbon (C). Si²⁺ spectrum 33, Si³⁺ spectrum 32, and Si⁴⁺ spectrum 31 are related to a bond between silicon (Si) and oxygen (O).

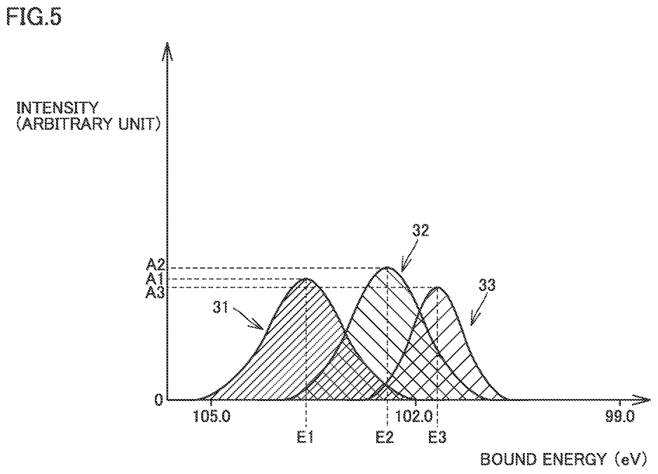

FIG. 5 is a schematic view showing an area of Si²⁺ spectrum 33, an area of Si³⁺ spectrum 32, and an area of Si⁴⁺ spectrum 31. The area of Si²⁺ spectrum 33 is an area of a region surrounded by Si²⁺ spectrum 33 and the horizontal axis. To be specific, the area of Si²⁺ spectrum 33 is the area of the region indicated by coarse hatching from the lower left to the upper right. The area of Si³⁺ spectrum 32 is an area of a region surrounded by Si³⁺ spectrum 32 and the horizontal axis. To be specific, the area of Si³⁺ spectrum 32 is the area of the region indicated by hatching from the upper left to the lower right.

Similarly, the area of Si⁴⁺ spectrum 31 is an area of a region surrounded by Si⁴⁺ spectrum 31 and the horizontal axis. To be specific, the area of Si⁴⁺ spectrum 31 is the area of the region indicated by the thin hatching from the lower left to the upper right. The sum of the area of Si²⁺ spectrum 33, the area of Si³⁺ spectrum 32, and the area of Si⁴⁺ spectrum 31 is the sum of the areas of the respective spectra.

As shown in FIG. 5, bound energy (first energy E1) corresponding to a peak of Si⁴⁺ spectrum 31 is, for example, 104.5 eV. Bound energy (second energy E2) corresponding to a peak of Si³⁺ spectrum 32 is, for example, 103.8 eV. Bound energy (third energy E3) corresponding to a peak of Si²⁺ spectrum 33 is, for example, 103.2 eV.

Peak intensity (second peak intensity A2) of Si³⁺ spectrum 32 may be higher than peak intensity (first peak intensity A1) of Si⁴⁺ spectrum 31. The peak intensity (second peak intensity A2) of Si³⁺ spectrum 32 may be higher than a peak intensity (third peak intensity A3) of Si²⁺ spectrum 33. The peak intensity (first peak intensity A1) of Si⁴⁺ spectrum 31 may be higher than the peak intensity (third peak intensity A3) of Si²⁺ spectrum 33.

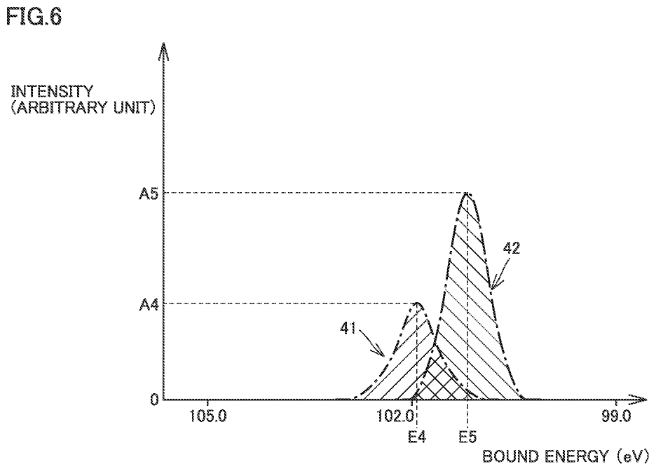

FIG. 6 is a schematic view showing an area of Si 2p_{1/2} spectrum 41 and an area of Si 2p_{3/2} spectrum 42. As shown in FIG. 6, the area of Si 2p_{1/2} spectrum 41 is an area of a region surrounded by Si 2p_{1/2} spectrum 41 and the horizontal axis. To be specific, the area of Si 2p_{1/2} spectrum 41 is the area of the region indicated by hatching from the lower left to the upper right. Similarly, the area of Si 2p_{3/2} spectrum 42 is an area of a region surrounded by Si 2p_{3/2} spectrum 42 and the horizontal axis. To be specific, the area of Si 2p_{3/2} spectrum 42 is the area of the region indicated by hatching from the upper left to the lower right. A sum of the area of Si 2p_{1/2} spectrum 41 and the area of Si 2p_{3/2} spectrum 42 is a sum of the areas of the respective spectra.

As shown in FIG. 6, bound energy (fourth energy E4) corresponding to a peak of Si 2p_{1/2} spectrum 41 is, for example, 101.8 eV. Bound energy (fifth energy E5) corresponding to a peak of Si 2p_{3/2} spectrum 42 is, for example, 100.8 eV. Peak intensity (fifth peak intensity A5) of Si 2p_{3/2} spectrum 42 may be higher than peak intensity (fourth peak intensity A4) of Si 2p_{1/2} spectrum 41.

According to SiC crystal substrate 10 in the embodiment, in the X-ray photoelectron spectrum under conditions of the incident X-ray energy of 250 eV and the photoelectron take-off angle of 45 degrees, when the sum of the area of Si 2p_{1/2} spectrum 41 and the area of Si 2p_{3/2} spectrum 42 is 1, the sum of the area of Si²⁺ spectrum 33, the area of Si³⁺ spectrum 32, and the area of Si⁴⁺ spectrum 31 is smaller than 1.8. From another viewpoint, a value obtained by dividing the sum of the area of Si²⁺ spectrum 33, the area of Si³⁺ spectrum 32, and the area of Si⁴⁺ spectrum 31 by the sum of the area of Si 2p_{1/2} spectrum 41 and the area of Si 2p_{3/2} spectrum 42 is smaller than 1.8.

When the sum of the area of Si 2p_{1/2} spectrum 41 and the area of Si 2p_{3/2} spectrum 42 is 1, the sum of the area of Si²⁺ spectrum 33, the area of Si³⁺ spectrum 32, and the area of Si⁴⁺ spectrum 31 is not particularly limited, but may be smaller than 1.1, smaller than 1.0, smaller than 0.9, or smaller than 0.85, for example.

When the sum of the area of Si 2p_{1/2} spectrum 41 and the area of Si 2p_{3/2} spectrum 42 is 1, the sum of the area of Si²⁺ spectrum 33, the area of Si³⁺ spectrum 32, and the area of Si⁴⁺ spectrum 31 is not particularly limited, but may be larger than 0.6, larger than 0.7, or larger than 0.75, for example.

According to SiC crystal substrate 10 in the embodiment, in the X-ray photoelectron spectrum under conditions of the incident X-ray energy of 100 eV and the photoelectron take-off angle of 45 degrees, when the sum of the area of Si 2p_{1/2} spectrum 41 and the area of Si 2p_{3/2} spectrum 42 is 1, the sum of the area of Si²⁺ spectrum 33, the area of Si³⁺ spectrum 32, and the area of Si⁴⁺ spectrum 31 is smaller than 1.8. From another viewpoint, a value obtained by dividing the sum of the area of Si²⁺ spectrum 33, the area of Si³⁺ spectrum 32, and the area of Si⁴⁺ spectrum 31 by the sum of the area of Si 2p_{1/2} spectrum 41 and the area of Si 2p_{3/2} spectrum 42 is smaller than 4.1.

When the sum of the area of Si 2p_{1/2} spectrum 41 and the area of Si 2p_{3/2} spectrum 42 is 1, the sum of the area of Si²⁺ spectrum 33, the area of Si³⁺ spectrum 32, and the area of Si⁴⁺ spectrum 31 is not particularly limited, but may be smaller than 3.5, smaller than 3.0, smaller than 2.7, or smaller than 2.3, for example.

When the sum of the area of Si 2p_{1/2} spectrum 41 and the area of Si 2p_{3/2} spectrum 42 is 1, the sum of the area of Si²⁺ spectrum 33, the area of Si³⁺ spectrum 32, and the area of Si⁴⁺ spectrum 31 is not particularly limited, but may be larger than 1.5, larger than 1.9, or larger than 2.1, for example.

### (X-ray Absorption Coefficient Microstructure: XAFS)

Next, a method of measuring an X-ray absorption coefficient microstructure will be described. The X-ray absorption coefficient microstructure is measured using Sumitomo Electric Beamline BL17 in SAGA Light Source.

The X-ray absorption coefficient microstructure is obtained by measuring an X-ray absorption coefficient spectrum 60. An X-ray application position at the time of measure of X-ray absorption coefficient spectrum 60 is the same as the X-ray application position at the time of measure of X-ray photoelectron spectrum 20. In the X-ray absorption coefficient microstructure by an electron yield method, a sample current of a sample (SiC crystal substrate 10) is measured while scanning the incident X-ray energy, and the X-ray absorption coefficient is obtained from the ratio of the sample current intensity to the incident X-ray intensity. X-ray absorption coefficient spectrum 60 may be analyzed using analysis software (Athena).

An example of measure of a K-edge absorption XAFS spectrum of Si by the electron yield method using BL17 Sumitomo Electric Beamline in SAGA Light Source is shown. The specifications of the Beamline and the measurement conditions of X-ray absorption coefficient spectrum 60 are as follows.

### <Specifications of Sumitomo Electric Beamline BL17>

Light source: polarization electromagnet
Spectroscope: variable deviation angle diffraction grating spectroscope (400 lines/mm 1000 lines/mm 1400 lines/mm 2200 lines/mm)
Energy range: 50 to 2000 eV
Number of photons: >10⁹ photons/second @ 50 to 1400 eV
Energy resolution: E/ΔE>3480 @ 400 eV
Beam size: 0.95 mm (height)×0.05 mm (width)
Measuring device: XPS, XAFS

### <Measurement Condition>

Diffraction grating: 1000 lines/mm
Incident X-ray energy: 1810 to 1900 eV
Measurement energy step: Δ0.5 eV (1810 to 1834 eV, 1865 to 1900 eV), Δ0.2 eV (1834 to 1865 eV)
Integration time: 1 second/step
Measurement method: electron yield method
Detection method: I0: M3 mirror current at the most downstream of the Beamline, I1: sample current, both using a picoammeter (model number: 6485) manufactured by Keithley Instruments.

Sample fixing: The sample and the sample holder are fixed with a carbon tape. The carbon tape is not applied with X-rays.

Sample surface treatment: not performed

Vacuum degree of measurement chamber: 7×10⁻⁸ Pa or less

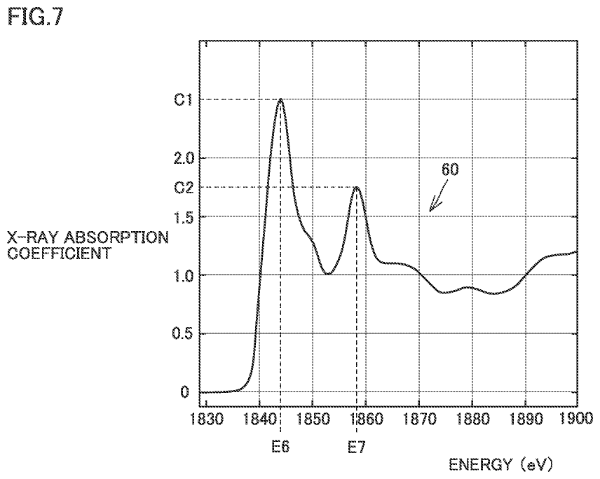

FIG. 7 is a schematic view showing X-ray absorption coefficient spectrum 60 of SiC crystal substrate 10 in the embodiment. In FIG. 7, the horizontal axis represents the incident X-ray energy (unit: eV), and the vertical axis represents normalized X-ray absorption coefficient. However, the horizontal axis may be calibrated with the white line of silica as 1846.8 eV. In order to normalize the X-ray absorption coefficient on the vertical axis, software capable of analyzing an XANES spectrum is used. The sample current intensity for each X-ray energy obtained from the sample is plotted, the range of the X-ray energy between two arbitrary points in the range of the X-ray energy from 1810 eV to 1830 eV is subtracted as a background region, and the range of the X-ray energy between two arbitrary points in the range of the X-ray energy from 1870 eV to 1900 eV is set as a normalization region. Further, the two points defining the background region are separated from each other by at least 10 eV. The two points defining the normalized region are separated from each other by at least 20 eV.

In FIG. 7, a Si—K edge is shown. As shown in FIG. 7, the peaks of X-ray absorption coefficient spectrum 60 are observed at each of positions of a sixth energy E6 and a seventh energy E7 of the incident X-ray energy. Sixth energy E6 is, for example, 1843 eV. Seventh energy E7 is, for example, 1858 eV. The normalized X-ray absorption coefficient at sixth energy E6 is a first X-ray absorption coefficient C1. The normalized X-ray absorption coefficient at seventh energy E7 is a second X-ray absorption coefficient C2. As shown in FIG. 7, the background of X-ray absorption coefficient spectrum 60 is processed so that the normalized X-ray absorption coefficient near 1830 eV of the incident X-ray energy is substantially zero.

In X-ray absorption coefficient spectrum 60, a degree of Si bonding other than the bonding between Si and C can be estimated. From another viewpoint, a degree of bonding between Si and an element other than C is quantitatively estimated. The X-ray absorption coefficient of a peak between 1840 eV and 1850 eV of X-ray absorption coefficient spectrum 60 and the X-ray absorption coefficient of a peak between 1855 eV and 1865 eV of X-ray absorption coefficient spectrum 60 are related to the degree of bonding between Si and C. When the degree of bonding between Si and an element other than C (for example, O) increases, the X-ray absorption coefficient of the peak between 1855 eV and 1865 eV of X-ray absorption coefficient spectrum 60 becomes smaller. Therefore, as a thickness of an oxide on the surface of SiC crystal substrate 10 increases, the X-ray absorption coefficient of the peak between 1855 eV and 1865 eV of X-ray absorption coefficient spectrum 60 becomes smaller.

In SiC crystal substrate 10 in the embodiment, when the X-ray absorption coefficient of the peak between 1840 eV and 1850 eV of X-ray absorption coefficient spectrum 60 is 1, the X-ray absorption coefficient of the peak between 1855 eV and 1865 eV of X-ray absorption coefficient spectrum 60 may be larger than 0.45. From another viewpoint, the value obtained by dividing second X-ray absorption coefficient C2 by first X-ray absorption coefficient C1 (C2/C1) is larger than 0.45. The larger the value obtained by dividing second X-ray absorption coefficient C2 by first X-ray absorption coefficient C1 (C2/C1), the smaller the degree of bonding between Si and an element other than C. In this case, it is considered that the presence ratio of foreign substances such as oxides on the surface of SiC crystal substrate 10 is low, and unmixed bonding between Si and C is dominant.

When the X-ray absorption coefficient of the peak between 1840 eV and 1850 eV of X-ray absorption coefficient spectrum 60 is 1, the X-ray absorption coefficient of the peak between 1855 eV and 1865 eV of X-ray absorption coefficient spectrum 60 is not particularly limited, but may be larger than 0.5, larger than 0.55, or larger than 0.59, for example.

When the X-ray absorption coefficient of the peak between 1840 eV and 1850 eV of X-ray absorption coefficient spectrum 60 is 1, the X-ray absorption coefficient of the peak between 1855 eV and 1865 eV of X-ray absorption coefficient spectrum 60 is not particularly limited, but may be smaller than 0.8, smaller than 0.7, or smaller than 0.65, for example.

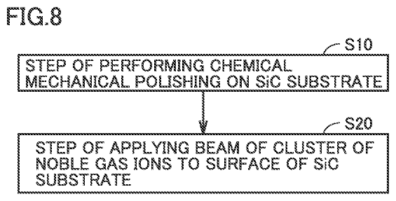

Next, a method of manufacturing SiC crystal substrate 10 according to the embodiment will be described. FIG. 8 is a flow chart schematically showing the method of manufacturing SiC crystal substrate 10 according to the embodiment. As shown in FIG. 8, the method of manufacturing SiC crystal substrate 10 according to the embodiment mainly includes a step of performing chemical mechanical polishing on an SiC substrate 50 (S10) and a step of applying a beam of a cluster of noble gas ions to a surface of SiC substrate 50 (S20).

First, an ingot made of silicon carbide single crystal of polytype 4H is formed by, for example, a sublimation method. After the ingot is shaped, the ingot is sliced by a multi-wire saw apparatus. Thus, SiC substrate 50 is cut out from the ingot.

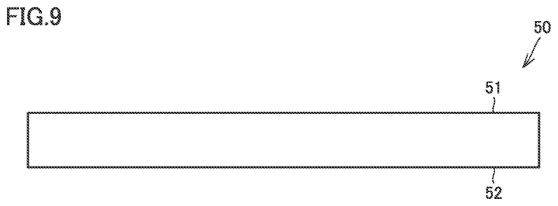

FIG. 9 is a schematic cross-sectional view showing a configuration of SiC substrate 50. As shown in FIG. 9, SiC substrate 50 has a first surface 51 and a second surface 52. Second surface 52 is opposite to first surface 51. The thickness of SiC substrate 50 is, for example, 1 mm. First surface 51 is a plane off by an angle 4° or less in the <11-20> direction with respect to the {0001} plane, for example. Specifically, first surface 51 may be a plane off by an angle of approximately 4° or less with respect to the (0001) plane, or may be a surface off by an angle of approximately 4° or less with respect to the (000-1) plane, for example.

Next, mechanical polishing is performed on a silicon carbide single crystal substrate. Specifically, each of first surface 51 and second surface 52 is polished by a slurry. The slurry contains, for example, diamond abrasive grains. The diameter of the diamond abrasive grains is, for example, 0.1 μm. The load is, for example, 200 g/cm². In this way, mechanical polishing is performed on SiC substrate 50 at each of first surface 51 and second surface 52.

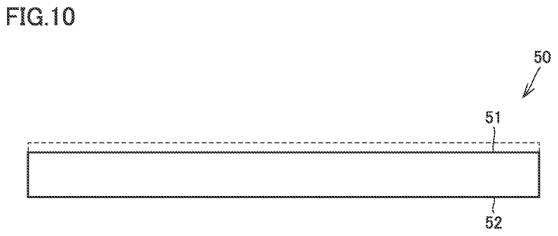

Next, the step of performing chemical mechanical polishing on SiC substrate 50 (S10) is performed. FIG. 10 is a schematic cross-sectional view showing the step of performing chemical mechanical polishing on SiC substrate 50. The portion indicated by the dashed line in FIG. 10 shows the state before chemical mechanical polishing. Chemical mechanical polishing is performed on first surface 51 of SiC substrate 50 using a polishing liquid. Thus, a part of SiC substrate 50 is removed on first surface 51. The polishing liquid contains, for example, abrasive grains and an oxidizing agent. The abrasive grains are, for example, colloidal silica. The average grain diameter of the abrasive grains is, for example, 20 nm. The oxidizing agent is, for example, hydrogen peroxide, permanganate, nitrate, hypochlorite, or the like. The polishing liquid is, for example, DSC-0902 manufactured by Fujimi Incorporated.

First surface 51 of SiC substrate 50 is disposed so as to face a polishing cloth. The polishing cloth is, for example, a nonwoven fabric (SUBA800) manufactured by Nitta Haas Incorporated. The polishing liquid containing abrasive grains is supplied between first surface 51 and the polishing cloth. SiC substrate 50 is attached to a head. The rotation speed of the head is, for example, 60 rpm. The rotation speed of a platen on which the polishing cloth is provided is, for example, 60 rpm. The load is, for example, 180 g/cm².

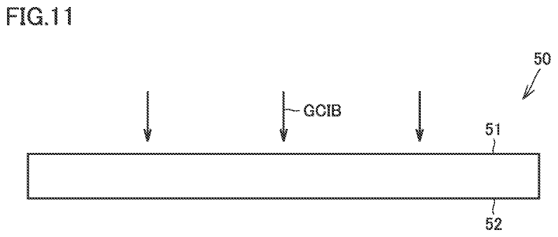

Next, the step of applying the beam of the cluster of noble gas ions to the surface of SiC substrate 50 (S20) is performed. FIG. 11 is a schematic cross-sectional view showing the step of applying the beam of the cluster of noble gas ions to the surface of SiC substrate 50. As shown in FIG. 11, the beam of the cluster of noble gas ions (gas cluster ion beam: GCIB) is applied to first surface 51 of SiC substrate 50. The noble gas ions are, for example, argon ions. The noble gas ions may be helium or the like.

The gas cluster ion beam is applied to first surface 51, and thus foreign substances such as slurry remaining on first surface 51 are removed. An oxide film formed on first surface 51 may be removed by the gas cluster ion beam.

In the step of applying the beam of the cluster of noble gas ions to the surface of SiC substrate 50, an acceleration voltage may be 5 kV to 10 kV. The acceleration voltage is not particularly limited, but may be, for example, 6 kV or more, or 7 kV or more. The acceleration voltage is not particularly limited, but may be, for example, 9 kV or less, or 8 kV or less.

In the step of applying the beam of the cluster of noble gas ions to the surface of SiC substrate 50, a current of the beam may be 5 nA to and 10 nA. The current of the beam is not particularly limited, but may be, for example, 6 nA or more, or 7 nA or more. The current of the beam is not particularly limited, but may be, for example, 9 nA or less, or 8 nA or less.

In the step of applying the beam of the cluster of noble gas ions to the surface of SiC substrate 50, an area of a region to which the beam is applied may be 1 mm² to 100 mm². The area of the region to which the beam is applied is not particularly limited, but may be, for example, 5 mm² or more, or 10 mm² or more. The area of the region to which the beam is applied is not particularly limited, but may be, for example, 90 mm² or less, or 80 mm² or less. An application time of the beam in each applied region is, for example, 1 second.

First surface 51 of SiC substrate 50 is scanned by the beam. Thus, the gas cluster ion beam is applied to almost entire first surface 51. As a result, foreign substances such as slurry and the oxide film are removed from almost entire first surface 51. First surface 51 is a surface on which an SiC epitaxial film is formed. In this way, SiC crystal substrate 10 according to the embodiment is manufactured (see FIG. 1).

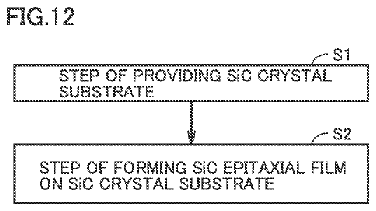

Next, a method of manufacturing an SiC epitaxial substrate 100 according to the embodiment will be described. FIG. 12 is a flow chart schematically showing the method of manufacturing SiC epitaxial substrate 100 according to the embodiment. As shown in FIG. 12, the method of manufacturing SiC epitaxial substrate 100 according to the embodiment mainly includes a step of providing an SiC crystal substrate (S1) and a step of forming the SiC epitaxial film on the SiC crystal substrate (S2).

First, the step of providing the SiC crystal substrate (S1) is performed. Specifically, SiC crystal substrate 10 is provided using the method of manufacturing SiC crystal substrate 10 according to the embodiment described above.

Next, the step of forming the SiC epitaxial film on the SiC crystal substrate (S2) is performed. The step of forming the SiC epitaxial film on the SiC crystal substrate (S2) is performed after the step of applying the beam of the cluster of noble gas ions (S20). Specifically, a mixed gas containing silane, propane, ammonia, and hydrogen is introduced into a film forming apparatus (not shown), and the mixed gas is thermally decomposed on SiC crystal substrate 10. Thus, an SiC epitaxial film 70 is formed on SiC crystal substrate 10.

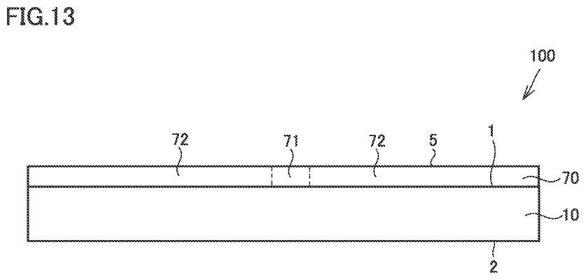

Next, a configuration of SiC epitaxial substrate 100 according to the embodiment will be described. FIG. 13 is a schematic cross-sectional view showing the configuration of SiC epitaxial substrate 100 according to the embodiment. As shown in FIG. 13, SiC epitaxial substrate 100 according to the embodiment includes SiC crystal substrate 10 and SiC epitaxial film 70. SiC epitaxial film 70 is disposed on SiC crystal substrate 10. SiC epitaxial film 70 includes a polycrystal region 71 and a single-crystal region 72. Polycrystal region 71 is contiguous with single-crystal region 72. SiC epitaxial film 70 has a surface 5. Surface 5 of SiC epitaxial film 70 may be constituted by polycrystal region 71 and single-crystal region 72.

In SiC epitaxial substrate 100 according to the embodiment, an area ratio of polycrystal region 71 in surface 5 of SiC epitaxial film 70 is less than 10%. The area ratio of polycrystal region 71 is not particularly limited, and may be less than 8% or less than 5%, for example. The area ratio of polycrystal region 71 is not particularly limited, but may be, for example, 0.1% or more, or 1% or more. The area ratio of polycrystal region 71 in surface 5 is a value obtained by dividing the area of polycrystal region 71 by the area of surface 5 when viewed in the direction perpendicular to surface 5.

Next, the function and effect of SiC crystal substrate 10 and the method of manufacturing SiC crystal substrate 10 according to the embodiment will be described.

For example, in the step of performing chemical mechanical polishing on the substrate, processing damage may occur on the surface of the substrate, or a chemical state (oxidation state) of the surface of the substrate may change. In this case, a region in which the degree of bonding between Si and an element other than C is high (hereinafter, also referred to as a “chemical state change region”) may be formed in a region of about 1 nm from the surface of the substrate. The chemical state change region is typically an oxide film such as silicon dioxide, but is not limited to the oxide film.

When the chemical state change region exists on the surface of SiC crystal substrate 10, a polycrystal may be generated in the SiC epitaxial film formed on the surface. In a normal XPS apparatus, since the incident X-ray energy is large (for example, about 2 keV), only average information of a region at a depth of about 10 nm from the surface can be measured. Therefore, in the normal XPS apparatus, it is not possible to extract information only on the extreme surface which is at a depth of about 2 nm from the surface. As a result, when a very thin chemical state change region exists on the surface of SiC crystal substrate 10, it is not possible to perform highly accurate quantitative analysis.

In SiC crystal substrate 10 according to the present disclosure, in X-ray photoelectron spectrum 20 under conditions of the incident X-ray energy of 250 eV and the photoelectron take-off angle of 45 degrees, when the sum of the area of Si 2p_{1/2} spectrum 41 and the area of Si 2p_{3/2} spectrum 42 is 1, the sum of the area of Si²⁺ spectrum 33, the area of Si³⁺ spectrum 32, and the area of Si⁴⁺ spectrum 31 is smaller than 1.8. Thus, SiC crystal substrate 10 in which the chemical state change region is hardly formed on the surface is obtained. Therefore, the ratio of generation of polycrystal in the SiC epitaxial film formed on SiC crystal substrate 10 can be reduced.

In SiC crystal substrate 10 according to the present disclosure, when the sum of the area of Si 2p_{1/2} spectrum 41 and the area of Si 2p_{3/2} spectrum 42 is 1, the sum of the area of Si²⁺ spectrum 33, the area of Si³⁺ spectrum 32, and the area of Si⁴⁺ spectrum 31 may be smaller than 1.1. This can further reduce the ratio of generation of polycrystal in the SiC epitaxial film formed on SiC crystal substrate 10.

In SiC crystal substrate 10 according to the present disclosure, when the X-ray absorption coefficient of the peak between 1840 eV and 1850 eV of X-ray absorption coefficient spectrum 60 is 1, the X-ray absorption coefficient of the peak between 1855 eV and 1865 eV of X-ray absorption coefficient spectrum 60 may be larger than 0.45. This can further reduce the ratio of generation of polycrystal in the SiC epitaxial film formed on SiC crystal substrate 10.

In SiC crystal substrate 10 according to the present disclosure, when the X-ray absorption coefficient of the peak between 1840 eV and 1850 eV of X-ray absorption coefficient spectrum 60 is 1, the X-ray absorption coefficient of the peak between 1855 eV and 1865 eV of X-ray absorption coefficient spectrum 60 may be larger than 0.55. This can further reduce the ratio of generation of polycrystal in the SiC epitaxial film formed on SiC crystal substrate 10.

In the method of manufacturing SiC crystal substrate 10 according to the present disclosure, after the step of performing chemical mechanical polishing on SiC substrate 50, the beam of the cluster of noble gas ions is applied to the surface of SiC substrate 50. Thus, the chemical state change region formed in the step of performing chemical mechanical polishing on SiC substrate 50 can be effectively removed. Therefore, the ratio of generation of polycrystal in the SiC epitaxial film formed on SiC crystal substrate 10 can be reduced.

In the method of manufacturing SiC crystal substrate 10 according to the present disclosure, in the step of applying the beam of the cluster of noble gas ions to the surface of SiC substrate 50, the acceleration voltage may be 5 kV to 10 kV. Thus, the chemical state change region formed in the step of performing chemical mechanical polishing on SiC substrate 50 can be more effectively removed. Therefore, the ratio of generation of polycrystal in the SiC epitaxial film formed on SiC crystal substrate 10 can be further reduced.

In the method of manufacturing SiC crystal substrate 10 according to the present disclosure, in the step of applying the beam of the cluster of noble gas ions to the surface of SiC substrate 50, the current of the beam may be 5 nA to 10 nA. Thus, the chemical state change region formed in the step of performing chemical mechanical polishing on SiC substrate 50 can be more effectively removed. Therefore, the ratio of generation of polycrystal in the SiC epitaxial film formed on SiC crystal substrate 10 can be further reduced.

In the method of manufacturing SiC crystal substrate 10 according the present disclosure, the surface is scanned by the beam. The area of the region to which the beam is applied may be 1 mm² to 100 mm². Thus, the chemical state change region formed in the step of performing chemical mechanical polishing on SiC substrate 50 can be more effectively removed. Therefore, the ratio of generation of polycrystal in the SiC epitaxial film formed on SiC crystal substrate 10 can be further reduced.

### EXAMPLES

### Sample Preparation

SiC crystal substrates 10 of samples 1 to 9 were prepared. SiC crystal substrates 10 of samples 1 to 4 were comparative examples. SiC crystal substrates 10 of samples 5 to 9 were examples. The diameters of SiC crystal substrates 10 of samples 1 to 9 were 100 mm (4 inches). Table 1 shows the manufacturing conditions of SiC crystal substrates 10 of samples 1 to 9. Condition 1 to condition 9 correspond to the manufacturing conditions of SiC crystal substrates 10 of sample 1 to sample 9, respectively. Other production conditions were as described above.

TABLE 1

| | Mechanical Polishing | | Chemical Mechanical | | GCIB | |
|---|---|---|---|---|---|---|
| | Abrasive | | Polishing | | Acceleration | |
| | Grain Size | Load | Oxidizing | Load | Voltage | Current |
| | (μm) | (g/cm²) | Agent | (g/cm²) | (kV) | (nA) |
| Condition 1 | ⅛ | 250 | — | — | — | — |
| Condition 2 | 1/10 | 200 | H₂O₂ | 200 | — | — |
| Condition 3 | 1/10 | 200 | KMnO₄ | 200 | — | — |
| Condition 4 | 1/10 | 200 | KMnO₄ | 180 | — | — |
| Condition 5 | 1/10 | 200 | KMnO₄ | 180 | 8 | 6 |
| Condition 6 | 1/10 | 200 | KMnO₄ | 180 | 8 | 7 |
| Condition 7 | 1/10 | 200 | KMnO₄ | 180 | 9 | 8 |
| Condition 8 | 1/10 | 200 | KMnO₄ | 180 | 9 | 9 |
| Condition 9 | 1/10 | 200 | KMnO₄ | 180 | 10 | 10 |

In condition 1, the abrasive grain size of the mechanical polishing was ⅛ μm, and the load was 250 g/cm². In condition 1, the step of performing chemical mechanical polishing (S10) and the step of applying a gas cluster ion beam (GCIB) (S20) were not performed.

In condition 2, the abrasive grain size of the mechanical polishing was 1/10 μm, and the load was 200 g/cm². In the step of performing chemical mechanical polishing (S10), oxygenated water (H₂O₂) was used as an oxidizing agent, and the load was 200 g/cm². In condition 2, the step of applying GCIB (S20) was not performed.

In condition 3, the abrasive grain size of the mechanical polishing was 1/10 μm, and the load was 200 g/cm². In the step of performing chemical mechanical polishing (S10), potassium permanganate (KMnO₄) was used as the oxidizing agent, and the load was 200 g/cm². In condition 3, the step of applying GCIB (S20) was not performed.

In condition 4, the abrasive grain size of the mechanical polishing was 1/10 μm, and the load was 200 g/cm². In the step of performing chemical mechanical polishing (S10), potassium permanganate (KMnO₄) was used as the oxidizing agent, and the load was 180 g/cm². In condition 4, the step of applying GCIB (S20) was not performed.

In condition 5, the abrasive grain size of the mechanical polishing was 1/10 μm, and the load was 200 g/cm². In the step of performing chemical mechanical polishing (S10), potassium permanganate (KMnO₄) was used as an oxidizing agent, and the load was 180 g/cm². In the step of applying GCIB (S20), the acceleration voltage was 8 kV, and the beam current was 6 nA.

In condition 6, the abrasive grain size of the mechanical polishing was 1/10 μm, and the load was 200 g/cm². In the step of performing chemical mechanical polishing (S10), potassium permanganate (KMnO₄) was used as the oxidizing agent, and the load was 180 g/cm². In the step of applying GCIB (S20), the acceleration voltage was 8 kV, and the beam current was 7 nA.

In condition 7, the abrasive grain size of the mechanical polishing was 1/10 μm, and the load was 200 g/cm². In the step of performing chemical mechanical polishing (S10), potassium permanganate (KMnO₄) was used as the oxidizing agent, and the load was 180 g/cm². In the step of applying GCIB (S20), the acceleration voltage was 9 kV, and the beam current was 8 nA.

In condition 8, the abrasive grain size of the mechanical polishing was 1/10 μm, and the load was 200 g/cm². In the step of performing chemical mechanical polishing (S10), potassium permanganate (KMnO₄) was used as the oxidizing agent, and the load was 180 g/cm². In the step of applying GCIB (S20), the acceleration voltage was 9 kV, and the beam current was 9 nA.

In condition 9, the abrasive grain size of the mechanical polishing was 1/10 μm, and the load was 200 g/cm². In the step of performing chemical mechanical polishing (S10), potassium permanganate (KMnO₄) was used as the oxidizing agent, and the load was 180 g/cm². In the step of applying GCIB (S20), the acceleration voltage was 10 kV, and the beam current was 10 nA.

### (Evaluation Method)

X-ray photoelectron spectrum 20 (XPS) and X-ray absorption coefficient spectrum 60 (XAFS) were measured for SiC crystal substrates 10 of samples 1 to 9. X-ray photoelectron spectrum 20 and X-ray absorption coefficient spectrum 60 were measured using Sumitomo Electric Beamline BL17 in SAGA Light Source. The measurement conditions were as described above.

X-ray photoelectron spectrum 20 of SiC crystal substrate 10 was separated into Si 2p_{1/2} spectrum 41, Si 2p_{3/2} spectrum 42, Si²⁺ spectrum 33, Si³⁺ spectrum 32, and Si⁴⁺ spectrum 31 by waveform separation using spectrum analysis software. Based on the five spectra obtained by waveform separation, the sum of the area of Si²⁺ spectrum 33, the area of Si³⁺ spectrum 32, and the area of Si⁴⁺ spectrum 31 was obtained when the sum of the area of Si 2p_{1/2} spectrum 41 and the area of Si 2p_{3/2} spectrum 42 was 1. Specifically, the sum of the area of Si²⁺ spectrum 33, the area of Si³⁺ spectrum 32, and the area of Si⁴⁺ spectrum 31 when the sum of the area of Si 2p_{1/2} spectrum 41 and the area of Si 2p_{3/2} spectrum 42 is set to 1 is the value obtained by dividing the sum of the area of Si²⁺ spectrum 33, the area of Si³⁺ spectrum 32, and the area of Si⁴⁺ spectrum 31 by the sum of the area of Si 2p_{1/2} spectrum 41 and the area of Si 2p_{3/2} spectrum 42.

Based on X-ray absorption coefficient spectrum 60 of SiC crystal substrate 10 according to each of the samples 1 to 9, the X-ray absorption coefficient of the peak between 1855 eV and 1865 eV of X-ray absorption coefficient spectrum 60 was obtained when X-ray absorption coefficient of the peak between 1840 eV and 1850 eV of X-ray absorption coefficient spectrum 60 was 1. Specifically, a value (C2/C1) was obtained by dividing second X-ray absorption coefficient C2 by first X-ray absorption coefficient C1.

Next, SiC epitaxial films were formed on SiC crystal substrates 10 of the samples 1 to 9. In the formation of the SiC epitaxial film, a hot-wall type horizontal Chemical Vapor Deposition (CVD) apparatus was used. First, SiC crystal substrate 10 was placed in a chamber of the CVD apparatus. Next, the chamber was heated to a temperature of about 1600° C. to 1700° C. Next, a gas mixture containing, for example, silane, propane, ammonia, and hydrogen was introduced into the chamber. Thus, the SiC epitaxial film was formed on SiC crystal substrate 10.

Next, the ratio of the area where polycrystals were generated in the SiC epitaxial film was obtained. In the region where the polycrystal is generated, the surface roughness is deteriorated as compared with the single-crystal region. The ratio of the area where polycrystals were generated was calculated by determining a point at which a surface roughness Sa was 1 nm or more as a region in which polycrystals were generated using an optical microscope (ECLIPSE LV150N manufactured by Nikon Corporation, analysis software: Bridgelements). The surface roughness Sa was measured at 20 points on surface 5 of SiC epitaxial substrate 100. Specifically, the measurement positions of the surface roughness Sa were set to points obtained by dividing a circle having a radius of 0.13 times the diameter of surface 5 into four equal parts (four points), points obtained by dividing a circle having a radius of 0.25 times the diameter of surface 5 into four equal parts (four points), and points obtained by dividing a circle having a radius of 0.40 times the diameter of surface 5 into 12 equal parts (12 points). The ratio of the area where polycrystals were generated was evaluated as “A” when it was less than 5% of the total area of the surface of the SiC epitaxial film, “B” when it was 5% or more and less than 10%, “C” when it was 10% or more and less than 25%, “D” when it was 25% or more and less than 50%, and “E” when it was 50% or more.

### Evaluation Result

TABLE 2

| | XPS | XAFS | |
|---|---|---|---|
| | First Measurement | Second | Ratio of Area of |
| | Value | Measurement | Polycrystals in |
| | (250 eV) | Value | Epitaxial Film |
| Sample 1 | 3.1 | — | E |
| Sample 2 | 2.8 | 0.3 | D |
| Sample 3 | 2.5 | 0.4 | C |
| Sample 4 | 2.2 | 0.4 | C |
| Sample 5 | 1.1 | 0.5 | B |
| Sample 6 | 0.8 | 0.6 | A |

Table 2 shows the first measurement value, the second measurement value, and the ratio of the area where polycrystals were generated in the SiC epitaxial film. The first measurement value is the sum of the area of Si²⁺ spectrum 33, the area of Si³⁺ spectrum 32, and the area of Si⁴⁺ spectrum 31 when the sum of the area of Si 2p_{1/2} spectrum 41 and the area of Si 2p_{3/2} spectrum 42 is 1, in the X-ray photoelectron spectrum under conditions of the incident X-ray energy of 250 eV and the photoelectron take-off angle of 45 degrees. The second measurement value is the X-ray absorption coefficient of the peak between 1855 eV and 1865 eV of X-ray absorption coefficient spectrum 60 when the X-ray absorption coefficient of the peak between 1840 eV and 1850 eV of X-ray absorption coefficient spectrum 60 is 1.

As shown in Table 2, it was found that when the SiC epitaxial film was formed on SiC crystal substrate 10 having a large sum of the area of Si²⁺ spectrum 33, the area of Si³⁺ spectrum 32, and the area of Si⁴⁺ spectrum 31 when the sum of the area of Si 2p_{1/2} spectrum 41 and the area of Si 2p_{3/2} spectrum 42 is 1, polycrystals were likely to be generated in the SiC epitaxial film.

Further, it was found that, when SiC epitaxial film was formed on SiC crystal substrate 10 having a small X-ray absorption coefficient of the peak between 1855 eV and 1865 eV of X-ray absorption coefficient spectrum 60 when the X-ray absorption coefficient of the peak between 1840 eV and 1850 eV of X-ray absorption coefficient spectrum 60 was 1, polycrystals were likely to be generated in the SiC epitaxial film.

The above results demonstrated that the use of SiC crystal substrates 10 (samples 5 and 6) having the sum of the area of Si²⁺ spectrum 33, the area of Si³⁺ spectrum 32, and the area of Si⁴⁺ spectrum 31 (first measurement value) was smaller than 1.8, when the sum of the area of Si 2p_{1/2} spectrum 41 and the area of Si 2p_{3/2} spectrum 42 was 1, was possible to suppress the generation of polycrystals in the SiC epitaxial film formed on SiC crystal substrate 10.

TABLE 3

| | XPS | Ratio of Area of |
|---|---|---|
| | Third Measurement Value | Polycrystals in |
| | (100 eV) | Epitaxial Film |
| Sample 4 | 4.1 | C |
| Sample 5 | 3.4 | B |
| Sample 7 | 3.0 | B |
| Sample 8 | 2.7 | A |
| Sample 9 | 2.4 | A |
| Sample 6 | 2.2 | A |

Table 3 shows the third measurement value and the ratio of the area where polycrystals were generated in the SiC epitaxial film. The third measurement value was the sum of the area of Si²⁺ spectrum 33, the area of Si³⁺ spectrum 32, and the area of Si⁴⁺ spectrum 31 when the sum of the area of Si 2p_{1/2} spectrum 41 and the area of Si 2p_{3/2} spectrum 42 was 1, in the X-ray photoelectron spectrum under conditions of the incident X-ray energy of 100 eV and the photoelectron take-off angle of 45 degrees.

As shown in Table 3, it was found that when the SiC epitaxial film was formed on SiC crystal substrate 10 having a large sum of the area of Si²⁺ spectrum 33, the area of Si³⁺ spectrum 32, and the area of Si⁴⁺ spectrum 31 when the sum of the area of Si 2p_{1/2} spectrum 41 and the area of Si 2p_{3/2} spectrum 42 was 1, polycrystals were likely to be generated in the SiC epitaxial film.

The above results demonstrated that by using SiC crystal substrates 10 (samples 5 to 9) having the sum of the area of Si²⁺ spectrum 33, the area of Si³⁺ spectrum 32, and the area of Si⁴⁺ spectrum 31 (third measurement value) is smaller than 4.1 when the sum of the area of Si 2p_{1/2} spectrum 41 and the area of Si 2p_{3/2} spectrum 42 was 1, it was possible to suppress the generation of polycrystals in the SiC epitaxial film formed on SiC crystal substrate 10.

The embodiments and examples disclosed herein are illustrative in all respects and should not be construed as limiting. The scope of the present invention is defined by the appended claims rather than the foregoing description, and is intended to include all modifications within the scope and meaning equivalent to the appended claims.

### REFERENCE SIGNS LIST

1 first main surface, 2 second main surface, 3 outer peripheral surface, 5 surface, 10 SiC crystal substrate, 20 X-ray photoelectron spectrum, 21 incident direction, 22 take-off direction, 23 photoelectron, 31 Si⁴⁺ spectrum, 32 Si³⁺ spectrum, 33 Si²⁺ spectrum, 41 Si 2p_{1/2} spectrum, 42 Si 2p_{3/2} spectrum, 50 substrate, 51 first surface, 52 second surface, 60 X-ray absorption coefficient spectrum, 70 SiC epitaxial film, 71 polycrystal region, 72 single-crystal region, 100 SiC epitaxial substrate, A1 first peak intensity, A2 second peak intensity, A3 third peak intensity, A4 fourth peak intensity, A5 fifth peak intensity, C1 first X-ray absorption coefficient, C2 second X-ray absorption coefficient, D analysis depth, E1 first energy, E2 second energy, E3 third energy, E4 fourth energy, E5 fifth energy, E6 sixth energy, E7 seventh energy.

1. An SiC crystal substrate, wherein in an X-ray photoelectron spectrum under conditions of incident X-ray energy of 250 eV and a photoelectron take-off angle of 45 degrees,
when a sum of an area of a Si 2p_{1/2} spectrum and an area of a Si 2p_{3/2} spectrum is 1, a sum of an area of a Si²⁺ spectrum, an area of a Si³⁺ spectrum, and an area of a Si⁴⁺ spectrum is smaller than 1.8.

2. The SiC crystal substrate according to claim 1, wherein when the sum of the area of the Si 2p_{1/2} spectrum and the area of the Si 2p_{3/2} spectrum is 1, the sum of the area of the Si²⁺ spectrum, the area of the Si³⁺ spectrum, and the area of the Si⁴⁺ spectrum is smaller than 1.1.

3. An SiC crystal substrate, wherein in an X-ray photoelectron spectrum under conditions of incident X-ray energy of 100 eV and a photoelectron take-off angle of 45 degrees,
when a sum of an area of a Si 2p_{1/2} spectrum and an area of a Si 2p_{3/2} spectrum is 1, a sum of an area of a Si²⁺ spectrum, an area of a Si³⁺ spectrum, and an area of a Si⁴⁺ spectrum is smaller than 4.1.

4. The SiC crystal substrate according to claim 3, wherein when the sum of the area of the Si 2p_{1/2} spectrum and the area of the Si 2p_{3/2} spectrum is 1, the sum of the area of the Si²⁺ spectrum, the area of the Si₃₊ spectrum, and the area of the Si⁴⁺ spectrum is smaller than 3.0.

5. The SiC crystal substrate according to claim 1, wherein when an X-ray absorption coefficient of a peak between 1840 eV and 1850 eV of an X-ray absorption coefficient spectrum is 1,
an X-ray absorption coefficient of a peak between 1855 eV and 1865 eV of the X-ray absorption coefficient spectrum is larger than 0.45.

6. The SiC crystal substrate according to claim 5, wherein when the X-ray absorption coefficient of the peak between 1840 eV and 1850 eV of the X-ray absorption coefficient spectrum is 1,
the X-ray absorption coefficient of the peak between 1855 eV and 1865 eV of the X-ray absorption coefficient spectrum is larger than 0.55.

7. An SiC epitaxial substrate comprising:
the SiC crystal substrate according to claim 1; and
an SiC epitaxial film disposed on the SiC crystal substrate.

8. A method of manufacturing an SiC crystal substrate, the method comprising:
performing chemical mechanical polishing on an SiC substrate; and
applying, after the performing chemical mechanical polishing, a beam of a cluster of noble gas ions to a surface of the SiC substrate.

9. The method of manufacturing an SiC crystal substrate according to claim 8, wherein in the applying a beam, an acceleration voltage is 5 kV to 10 kV.

10. The method of manufacturing an SiC crystal substrate according to claim 8, wherein in the applying a beam, a current of the beam is 5 nA to 10 nA.

11. The method of manufacturing an SiC crystal substrate according to claim 8, wherein in the applying a beam, the surface is scanned by the beam, and
an area of a region to which the beam is applied is 1 mm² to 100 mm².

12. A method of manufacturing an SiC epitaxial substrate, the method comprising:
providing an SiC crystal substrate manufactured by the method of manufacturing an SiC crystal substrate according to claim 8; and
forming, after the applying a beam, an SiC epitaxial film on the SiC crystal substrate.

13. An SiC epitaxial substrate comprising:
an SiC crystal substrate; and
an SiC epitaxial film disposed on the SiC crystal substrate,
wherein an area ratio of a polycrystal region in a surface of the SiC epitaxial film is less than 10%.
